(19) United States
(12) Patent Application Publication
(10) Pub. No.: US 2026/0114029 A1
(43) Pub. Date: Apr. 23, 2026

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Feng-Yun CHENG, Kaohsiung City (TW); Chia-Chen SUN, Kaohsiung City (TW)

(73) Assignee: UNITED MICROELECTRONICS CORP., Hsin-Chu City (TW)

(21) Appl. No.: 18/950,196

(22) Filed: Nov. 18, 2024

(30) Foreign Application Priority Data
Oct. 17, 2024 (TW) 113139499

(51) Int. Cl. H10D 84/80; H10D 1/00; H10D 84/01

(52) U.S. Cl. CPC H10D 84/817; H10D 1/021; H10D 84/0151

(57) ABSTRACT

A method for fabricating a semiconductor device includes the steps of first providing a substrate having a planar device region and a non-planar device region, forming fin-shaped structures on the non-planar device region, forming a first shallow trench isolation (STI) around the substrate on the planar device region, forming a second shallow trench isolation (STI) around the fin-shaped structures, forming first gate structures on the substrate of the planar device region, forming second gate structures on the fin-shaped structures, forming a first resistor on the first STI, and forming a second resistor on the second STI.

### BACKGROUND OF THE INVENTION

### 1. Field of the Invention

The invention relates to a method of fabricating semiconductor device, and more particularly to a method of integrating high-voltage (HV) device and low-voltage (LV) device.

### 2. Description of the Prior Art

In current semiconductor processing, controllers, memories, circuits of low-voltage operation and power devices of high-voltage operation are largely integrated into a single chip to achieve a single-chip system. The power device or high-voltage (HV) device, such as vertical double-diffusion metal-oxide-semiconductor (VDMOS), insulated gate bipolar transistor (IGBT) and lateral diffusion MOS (LDMOS), is employed to increase power switching efficiency and decrease the loss of energy resources. It is often required that the switching transistors withstand high breakdown voltages and operate at a low on-resistance.

Moreover with the trend in the industry being towards scaling down the size of the metal oxide semiconductor transistors (MOS), three-dimensional or non-planar transistor technology, such as fin field effect transistor technology (FinFET) has been developed to replace planar MOS transistors. Since the three-dimensional structure of a FinFET increases the overlapping area between the gate and the fin-shaped structure of the silicon substrate, the channel region can therefore be more effectively controlled. This way, the drain-induced barrier lowering (DIBL) effect and the short channel effect are reduced. The channel region is also longer for an equivalent gate length, thus the current between the source and the drain is increased. In addition, the threshold voltage of the fin FET can be controlled by adjusting the work function of the gate.

However as the scale of current devices continue to decrease the integration of high-voltage devices and FinFET devices start to face numerous challenges such as current leakage and control of breakdown voltage. Hence, how to improve the current fabrication for improving performance of the device has become an important task in this field.

### SUMMARY OF THE INVENTION

According to an embodiment of the present invention, a method for fabricating a semiconductor device includes the steps of first providing a substrate having a planar device region and a non-planar device region, forming fin-shaped structures on the non-planar device region, forming a first shallow trench isolation (STI) around the substrate on the planar device region, forming a second shallow trench isolation (STI) around the fin-shaped structures, forming first gate structures on the substrate of the planar device region, forming second gate structures on the fin-shaped structures, forming a first resistor on the first STI, and forming a second resistor on the second STI.

According to another aspect of the present invention, a semiconductor device includes a substrate having a planar device region and a non-planar device region, a first resistor on the planar device region, a second resistor on the non-planar device region, first gate structures around the first resistor, and second gate structures around the second resistor.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-3 illustrate a method for fabricating a semiconductor device according to an embodiment of the present invention.

FIG. 4 illustrates a top view of a semiconductor device according to an embodiment of the present invention.

### DETAILED DESCRIPTION

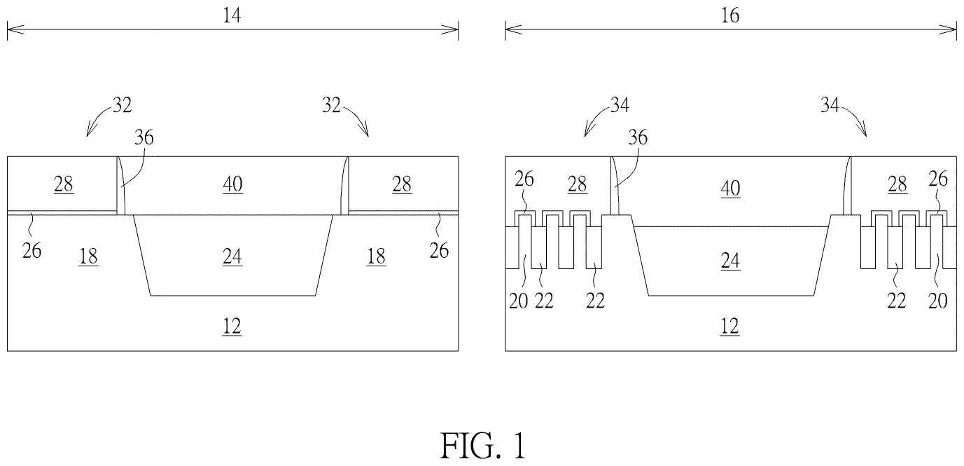

Referring to FIGS. 1-3, FIGS. 1-3 illustrate a method for fabricating a semiconductor device according to an embodiment of the present invention. As shown in FIG. 1, a substrate 12, such as a silicon substrate or silicon-on-insulator (SOI) substrate is provided and a planar device region 14 and a non-planar device region 16 are defined on the substrate 12, in which the planar device region 14 could include a high-voltage (HV) region used for accommodating HV devices while the non-planar device region 16 includes a low-voltage (LV) region used for accommodating LV devices fabricated in the later process.

In this embodiment, the planar device region 14 and the non-planar device region 16 could be transistor regions having same conductive type or different conductive types. For instance, each of the two regions 14, 16 could be a PMOS region or a NMOS region and the two regions 14 and 16 are defined to fabricate gate structures having different threshold voltages in the later process. Preferably, it would be desirable to first conduct an implantation process to form p-type deep wells on the planar device region 14 and a n-type deep well on the non-planar device region 16, but not limited thereto.

Next, a base 18 is formed on the planar device region 14 and a plurality of fin-shaped structures 20 are formed on the substrate 12 of the non-planar device region 16. Preferably, the fin-shaped structures 20 could be obtained by a sidewall image transfer (SIT) process. For instance, a layout pattern is first input into a computer system and is modified through suitable calculation. The modified layout is then defined in a mask and further transferred to a layer of sacrificial layer on a substrate through a photolithographic and an etching process. In this way, several sacrificial layers distributed with a same spacing and of a same width are formed on a substrate. Each of the sacrificial layers may be stripe-shaped. Subsequently, a deposition process and an etching process are carried out such that spacers are formed on the sidewalls of the patterned sacrificial layers. In a next step, sacrificial layers can be removed completely by performing an etching process. Through the etching process, the pattern defined by the spacers can be transferred into the substrate underneath, and through additional fin cut processes, desirable pattern structures, such as stripe patterned fin-shaped structures could be obtained.

Alternatively, the base 18 and the fin-shaped structures 20 could also be obtained by first forming a patterned mask (not shown) on the substrate, 12, and through an etching process, the pattern of the patterned mask is transferred to the substrate 12 to form the base 18 and the fin-shaped structures 20. Moreover, the formation of the base 18 and the fin-shaped structures 20 could also be accomplished by first forming a patterned hard mask (not shown) on the substrate 12, and a semiconductor layer composed of silicon germanium is grown from the substrate 12 through exposed patterned hard mask via selective epitaxial growth process to form the corresponding the base 18 and fin-shaped structures 20. These approaches for forming the base 18 and fin-shaped structures 20 are all within the scope of the present invention. According to an embodiment of the present invention, one or more liner and/or hard mask could be formed on the top surface of the base 18 and fin-shaped structures 20 during the above patterning process, in which the liner and hard mask could include silicon oxide (SiO₂) or silicon nitride (SiN), but not limited thereto.

Next, shallow trench isolations (STIs) 22, 24 could be formed in the base 18 of the planar device region 14 and around the fin-shaped structures 20 on the non-planar device region 16. For instance, a flowable chemical vapor deposition (FCVD) process could be conducted to form an insulating layer (not shown) made of silicon oxide on the base 18 and fin-shaped structures 20 and fill the trenches between fin-shaped structures 20, and then a planarizing process such as chemical mechanical polishing (CMP) process is conducted to remove part of the insulating layer so that the top surface of the insulating layer is even with the top surface of the fin-shaped structures. At this stage, the remaining insulating layer around the fin-shaped structures 20 on the non-planar device region 16 preferably become a STI 22.

Next, a photo-etching process could be conducted to remove part of the base 18 on the planar device region 14 and even part of the fin-shaped structures 20 and part of the substrate 12 on the non-planar device region 16 for forming a plurality of trenches (not shown). Next, a sub-atmospheric chemical vapor deposition (SACVD) process is conducted to form another insulating layer on the planar device region 14 and non-planar device region 16 and fill the trenches, and then a planarizing process such as CMP is conducted to remove part of the insulating layer. At this stage, the remaining insulating layer around the base 18 of the planar device region 14 and the fin-shaped structures 20 of the non-planar device region 16 then becomes a STI 24 while the top surface of the STI 24 could be even with or not even with the top surface of the STI 22 on the non-planar device region 16.

Next, part of the STIs 22, 24 on the planar device region 14 and non-planar device region 16 could be removed, in which the top surface of the remaining STI 24 on the planar device region 14 is even with or slightly higher than the top surface of the surrounding base 18, the top surface of the STI 22 on the non-planar device region 16 is slightly lower than the top surface of the fin-shaped structures 20, and the top surface of the STI 24 on the non-planar device region 16 could be even with or slightly higher than the top surface of the STI 22 on the same non-planar device region 16. In this embodiment, the depth of the STI 22 on the non-planar device region 16 is less than the depth of the STI 24 on the planar device region 14. For instance, the depth of the STI 22 on the non-planar device region 16 is between 1200-1400 Angstroms or most preferably 1300 Angstroms and the depth of the STI 24 on the planar device region 14 is between 2200-2800 Angstroms or most preferably 2500 Angstroms.

Next, one or more oxidation process such as an in-situ steam generation (ISSG) process to form a gate dielectric layer 26 made of silicon oxide on the base 18 of planar device region 14 and fin-shaped structures 20 of non-planar device region 16. Next, gate structures 32, 34 or dummy gates could be formed on the base 18 and the fin-shaped structures 24 on the planar device region 14 and non-planar device region 16 respectively.

In this embodiment, the formation of the gate structures 32, 34 could be accomplished by a gate first process, a high-k first approach from gate last process, or a high-k last approach from gate last process. Since this embodiment pertains to a high-k last approach, a gate material layer 28 made of polysilicon and a selective hard mask (not shown) could be formed sequentially on the substrate 12 or gate dielectric layer 26, and a photo-etching process is then conducted by using a patterned resist (not shown) as mask to remove part of the gate material layer 28 and part of the gate dielectric layer 26 through single or multiple etching processes. After stripping the patterned resist, gate structures 32, 34 each made of a patterned gate dielectric layer 26 and a patterned material layer 28 are formed on the substrate 12, in which the patterned gate material layer 28 could be serving as gate electrodes in each region.

Next, at least a spacer 36 is formed on the sidewalls of each of the gate structures 32, 34 and then doped regions (not shown) or source/drain regions are formed in the substrate 12 adjacent to two sides of the gate structures 32, 34. In this embodiment, the spacer 36 could be a single spacer or a composite spacer, such as a spacer including but not limited to for example an offset spacer and a main spacer. Preferably, the offset spacer and the main spacer could include same material or different material while both the offset spacer and the main spacer could be made of material including but not limited to for example SiO₂, SiN, SiON, SiCN, or combination thereof. The doped regions or source/drain regions could include n-type dopants or p-type dopants depending on the type of device being fabricated.

Next, an interlayer dielectric (ILD) layer 40 made of silicon oxide is formed on the gate structures 32, 34 and the STIs 22, 24, and a planarizing process such as chemical mechanical polishing (CMP) process is conducted to remove part of the ILD layer 40 for exposing the gate material layer 28 so that the top surfaces of the gate material layer 28 and the ILD layer 40 are coplanar.

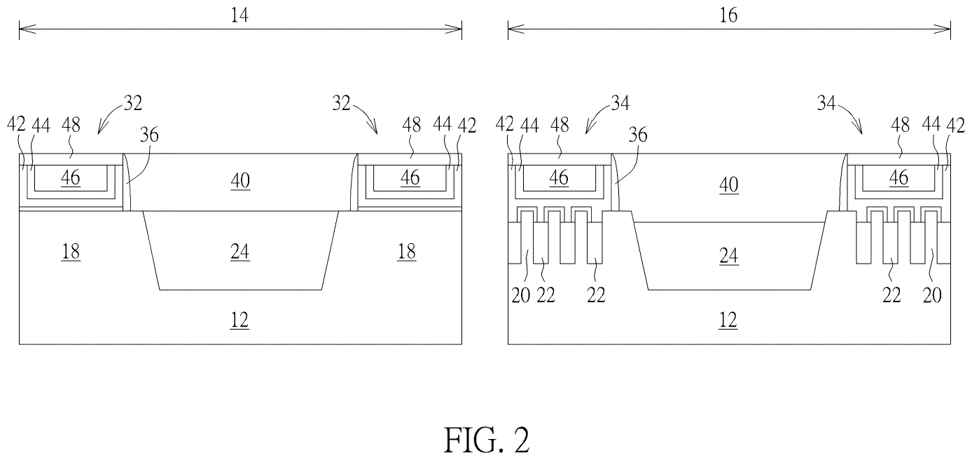

Next, as shown in FIG. 2, a replacement metal gate (RMG) process is conducted to transform the gate structures 32, 34 into metal gates. For instance, the RMG process could be accomplished by first performing a selective dry etching or wet etching process using etchants including but not limited to for example ammonium hydroxide (NH₄OH) or tetramethylammonium hydroxide (TMAH) to remove the gate material layers 28 and even the gate dielectric layer 26 from gate structures 32, 34 for forming recesses (not shown) in the ILD layer 40. Next, a high-k dielectric layer 42, a work function metal layer 44, and a low resistance metal layer 46 are formed in the recesses, and a planarizing process such as CMP is conducted to remove part of low resistance metal layer 46, part of work function metal layer 44, and part of the high-k dielectric layer 42 so that the top surfaces of the U-shape high-k dielectric layer 42, the U-shape work function metal layer 44, the low resistance metal layer 46, and the ILD layer 40 are coplanar. Preferably, the high-k dielectric layer 42, the work function metal layer 44, and the low resistance metal layer 46 altogether constitute a gate electrode for each of the transistors or devices.

In this embodiment, the high-k dielectric layer 42 is preferably selected from dielectric materials having dielectric constant (k value) larger than 4. For instance, the high-k dielectric layer 42 may be selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBi₂Ta₂O₉, SBT), lead zirconate titanate (PbZrₓTi₁₋ₓO₃, PZT), barium strontium titanate (BaₓSr₁₋ₓTiO₃, BST) or a combination thereof.

In this embodiment, the work function metal layer 44 is formed for tuning the work function of the metal gate in accordance with the conductivity of the device. For an NMOS transistor, the work function metal layer 44 having a work function ranging between 3.9 eV and 4.3 eV may include titanium aluminide (TiAl), zirconium aluminide (ZrAl), tungsten aluminide (WAl), tantalum aluminide (TaAl), hafnium aluminide (HfAl), or titanium aluminum carbide (TiAlC), but it is not limited thereto. For a PMOS transistor, the work function metal layer 44 having a work function ranging between 4.8 eV and 5.2 eV may include titanium nitride (TiN), tantalum nitride (TaN), tantalum carbide (TaC), but it is not limited thereto. An optional barrier layer (not shown) could be formed between the work function metal layer 44 and the low resistance metal layer 46 may include titanium (Ti), titanium nitride (TiN), tantalum (Ta) or tantalum nitride (TaN). Furthermore, the material of the low-resistance metal layer 46 may include copper (Cu), aluminum (Al), titanium aluminum (TiAl), cobalt tungsten phosphide (CoWP) or any combination thereof. Since the transformation of dummy gates into metal gates through RMG process is well known to those skilled in the art, the details of which are not explained herein for the sake of brevity. Next, part of the high-k dielectric layer 42, part of the work function metal layer 44, and part of the low resistance metal layer 46 are removed to form recesses (not shown), and a hard mask 48 is formed into each of the recesses so that the top surfaces of the hard masks 48 and the ILD layer 40 are coplanar. Preferably the hard masks 48 could include SiO₂, SiN, SiON, SiCN, or combination thereof.

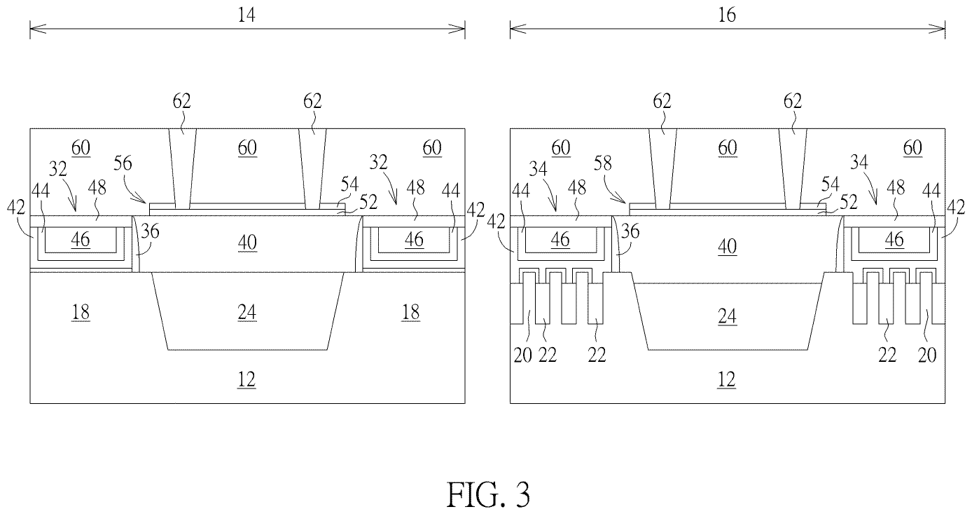

Next, as shown in FIG. 3, a high resistance metal layer 52 and a protective layer 54 are formed on the ILD layer 40 of each of the planar device region 14 and non-planar device region 16 and then a photo-etching process is conducted to remove part of the protective layer 54 and part of the high resistance metal layer 52 for forming resistors 56, 58 on the STI 24 of the planar device region 14 and non-planar device region 16 respectively. In this embodiment, the high resistance metal layer 52 preferably includes titanium nitride (TiN) and the protective layer 54 could include silicon oxide or silicon nitride.

Next, another ILD layer 60 is formed on the ILD layer 40 of the planar device region 14 and non-planar device region 16 and then contact plugs 62 are formed in the ILD layer 60 to electrically connect the resistors 56, 58 underneath. In this embodiment, the formation of the contact plugs 62 could be accomplished by first removing part of the ILD layer 60, part of the protective layer 54, and even part of the high resistance metal layer 52 for forming contact holes (not shown) exposing the high resistance metal layer 52, and then depositing a barrier/adhesive layer (not shown), a seed layer (not shown), and a conductive layer (not shown) into the contact holes, in which the barrier/adhesive layer is conformally deposited into the contact holes while the conductive layer is filled into the contact holes entirely. The barrier/adhesive layer may be consisted of tantalum (Ta), titanium (Ti), titanium nitride (TiN) or tantalum nitride (TaN), tungsten nitride (WN) or a suitable combination of metal layers such as Ti/TiN, but is not limited thereto. A material of the seed layer is preferably the same as a material of the conductive layer, and a material of the conductive layer may include a variety of low-resistance metal materials, such as aluminum (Al), titanium (Ti), tantalum (Ta), tungsten (W), niobium (Nb), molybdenum (Mo), copper (Cu) or the likes, preferably tungsten or copper, and most preferably tungsten. Next, a planarizing process such as CMP process and/or etching process is conducted to remove part of the barrier/adhesive layer, seed layer, and conductive layer so that the top surface of the remaining conductive layer is even with the top surface of the ILD layer 60 to form contact plugs 62. This completes the fabrication of a semiconductor device according to a preferred embodiment of the present invention.

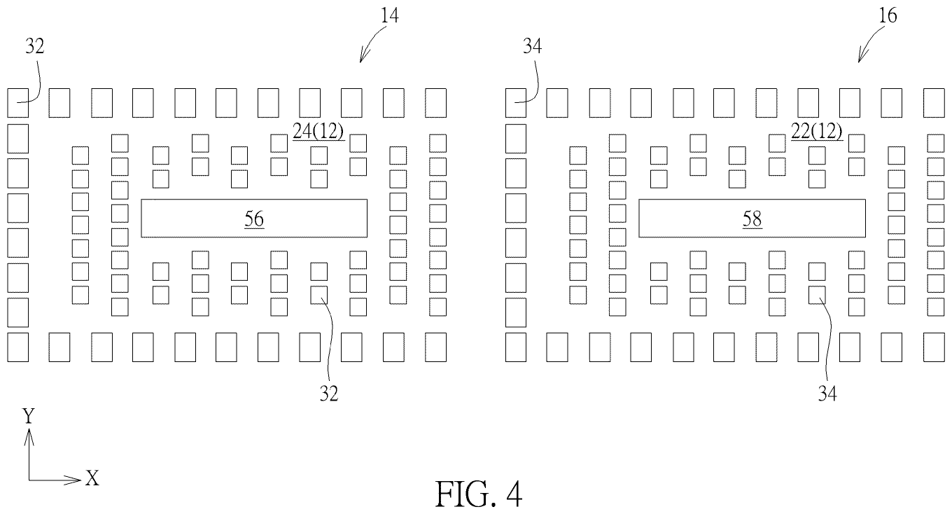

Referring to FIG. 4, FIG. 4 illustrates a top view of a semiconductor device according to an embodiment of the present invention. As shown in FIG. 4, the semiconductor device includes a planar device region 14 and a non-planar device region 16 defined on a substrate 12, a resistor 56 disposed on the planar device region 14, a resistor 58 disposed on the non-planar device region 16, a plurality of gate structures 32 around the resistor 56 on the planar device region 14, and a plurality of gate structures 34 around the resistor 58 on the non-planar device region 16. As disclosed previously, a base 18 or bases 18 are formed in the planar device region 14 for accommodating planar devices such as high-voltage (HV) devices while fin-shaped structures 20 are formed in the non-planar device region 16 for accommodating non-planar devices such as low-voltage (LV) devices.

Specifically, the resistors 56, 58 on the planar device region 14 and non-planar device region 16 are extending along a first direction such as X-direction while the gate structures 32, 34 are extending along a second direction such as Y-direction and surrounding the resistors 56, 58 on each region, in which the gate structures 32, 34 could have equal or different sizes, each of the gate structures 32, 34 under a top view perspective could include square or rectangular shapes, and the gate structures 32 on the planar device region 14 are disposed on the bases 18 while the gate structures 34 on the non-planar device region 16 are disposed on the fin-shaped structures 20.

It should further be noted that all the gate structures 32, 34 disposed on the planar device region 14 and non-planar device region 16 are dummy gate structures, such that even though the gate structures 32, 34 are fabricated along with active gate structures on other regions or the gate structures 32, 34 and other active gate structures share same composition, the gate structures 32, 34 and/or source/drain regions adjacent to the gate structures 32, 34 on the planar device region 14 and non-planar device region 16 are not electrically connected to external devices through contact plugs whatsoever.

Overall, the present invention discloses an embedded device, which preferably integrates resistors into HV devices on the planar device region and LV devices on the non-planar device region. Specifically, a resistor 56 could be disposed on the STI of the planar device region 14 and a plurality of dummy gate structures 32 are disposed on a base 18 around the resistor 56. Similarly, a resistor 58 could be disposed on the STI of the non-planar device region 16 and a plurality of dummy gate structures 34 are disposed on the fin-shaped structures 20 around the resistor 58. In contrast to only using a single resistor to measure resistance on different regions in current practice thereby resulting in Boolean calculation errors, the design of using different resistors on different regions to conduct measurement by present invention could minimize overall calculation errors significantly.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a semiconductor device, comprising:
providing a substrate having a planar device region and a non-planar device region;
forming a first resistor on the planar device region;
forming a second resistor on the non-planar device region;
forming first gate structures around the first resistor; and
forming second gate structures around the second resistor.

2. The method of claim 1, further comprising:
forming fin-shaped structures on the non-planar device region;
forming a first shallow trench isolation (STI) around the substrate on the planar device region;
forming a second shallow trench isolation (STI) around the fin-shaped structures;
forming the first gate structures on the substrate of the planar device region;
forming the second gate structures on the fin-shaped structures;
forming the first resistor on the first STI; and
forming the second resistor on the second STI.

3. The method of claim 1, wherein the planar device region comprises a high-voltage (HV) region.

4. The method of claim 1, wherein the non-planar device region comprises a low voltage (LV) region.

5. The method of claim 1, wherein the first gate structures comprise dummy gate structures.

6. The method of claim 1, wherein the first gate structures comprise dummy gate structures.

7. A semiconductor device, comprising:
a substrate having a planar device region and a non-planar device region;
a first resistor on the planar device region;
a second resistor on the non-planar device region;
first gate structures around the first resistor; and
second gate structures around the second resistor.

8. The semiconductor device of claim 7, further comprising:
fin-shaped structures on the non-planar device region;
a first shallow trench isolation (STI) around the substrate on the planar device region;
a second shallow trench isolation (STI) around the fin-shaped structures;
the first gate structures on the substrate of the planar device region;
the second gate structures on the fin-shaped structures;
the first resistor on the first STI; and
the second resistor on the second STI.

9. The semiconductor device of claim 7, wherein the planar device region comprises a high-voltage (HV) region.

10. The semiconductor device of claim 7, wherein the non-planar device region comprises a low voltage (LV) region.

11. The semiconductor device of claim 7, wherein the first gate structures comprise dummy gate structures.

12. The semiconductor device of claim 7, wherein the second gate structures comprise dummy gate structures.
